(19) United States
(12) Patent Application Publication
(10) Pub. No.: US 2026/0079627 A1
(43) Pub. Date: Mar. 19, 2026

(54) MEMORY SYSTEM WITH TEMPERATURE-BASED READ VOLTAGE ADJUSTMENT

(71) Applicant: Kioxia Corporation, Tokyo (JP)

(72) Inventors: Akihiko SAKAI, Fujisawa Kanagawa (JP); Masanobu SHIRAKAWA, Chigasaki Kanagawa (JP); Naomi TAKEDA, Yokohama Kanagawa (JP)

(21) Appl. No.: 19/066,373

(22) Filed: Feb. 28, 2025

(30) Foreign Application Priority Data
Sep. 13, 2024 (JP) 2024-159046

(51) Int. Cl. G06F 3/06; G11C 16/04; G11C 16/26

(52) U.S. Cl. CPC G06F 3/0614; G06F 3/0653; G06F 3/0679; G11C 16/0483; G11C 16/26

(57) ABSTRACT

According to some embodiments, a memory system includes a nonvolatile memory including a plurality of memory cells. The memory system includes a temperature sensor configured to acquire temperature data through temperature measurement. The memory system includes a buffer configured to store the temperature data; and a memory controller. When the nonvolatile memory executes a first operation in response to a first instruction transmitted from the memory controller, the temperature sensor acquires the temperature data representing a temperature of the nonvolatile memory in the first operation and the buffer stores the temperature data acquired by the temperature sensor as updated data. The nonvolatile memory transmits the temperature data stored in the buffer to the memory controller in response to a second instruction transmitted from the memory controller.

### CROSS-REFERENCE TO RELATED APPLICATION

This application is based upon and claims the benefit of priority from Japanese Patent Application No. 2024-159046, filed Sep. 13, 2024, the entire contents of which are incorporated herein by reference.

### FIELD

Embodiments described herein relate generally to a memory system.

### BACKGROUND

Memory systems that include nonvolatile memories capable of storing data in a nonvolatile manner and memory controllers controlling the nonvolatile memories are known.

Examples of related art include US-A-2022/0365505, US-A-2022/0269444, and US-A-2021/0383877.

### DESCRIPTION OF THE DRAWINGS

FIG. 1 is a block diagram illustrating an example of a configuration including a memory system and a host apparatus according to a first embodiment;

FIG. 2 is a block diagram illustrating an example of a configuration of a nonvolatile memory according to the first embodiment;

FIG. 3 is a circuit diagram illustrating an example of a circuit configuration of a memory cell array provided in the nonvolatile memory according to the first embodiment;

FIG. 4 is a schematic diagram illustrating an example of a threshold voltage distribution of memory cell transistors in the memory system according to the first embodiment;

FIG. 5 is a schematic diagram illustrating an example of temperature dependency of the threshold voltage distribution of the memory cell transistors in the memory system according to the first embodiment;

FIG. 6 is a schematic diagram illustrating an example of a command sequence of a read operation in the memory system according to the first embodiment;

FIG. 7 is a block diagram illustrating an example of a configuration including a memory system and a host apparatus according to a second embodiment;

FIG. 8 is a flowchart illustrating an operation example in the memory system according to the second embodiment;

FIG. 9 is a schematic diagram illustrating an example of a command sequence of an operation example in the memory system according to the second embodiment;

FIG. 10 is a block diagram illustrating an example of a configuration including a memory system and a host apparatus according to a third embodiment;

FIG. 11 is a flowchart illustrating an operation example in the memory system according to the third embodiment;

FIG. 12 is a schematic diagram illustrating an example of a command sequence of an operation example in the memory system according to the third embodiment;

FIG. 13 is a flowchart illustrating an operation example in a memory system according to a fourth embodiment;

FIG. 14 is a flowchart illustrating an operation example in a memory system according to a fifth embodiment;

FIG. 15 is a flowchart illustrating an operation example in a memory system according to a sixth embodiment;

FIG. 16 is a block diagram illustrating an example of a configuration including a memory system and a host apparatus according to a seventh embodiment;

FIG. 17 is a flowchart illustrating an operation example in the memory system according to the seventh embodiment; and

FIG. 18 is a flowchart illustrating an operation example in a memory system according to an eighth embodiment.

### DETAILED DESCRIPTION

Embodiments provide a memory system with improved reliability.

In general, according to one embodiment, a memory system includes: a nonvolatile memory including a plurality of memory cells, a temperature sensor configured to acquire temperature data through temperature measurement, and a buffer configured to store the temperature data; and a memory controller. When the nonvolatile memory executes a first operation in response to a first instruction transmitted from the memory controller, the temperature sensor acquires the temperature data for specifying (e.g., representing, indicating, and/or characterizing) a temperature of the nonvolatile memory in the first operation and the buffer stores the temperature data acquired by the temperature sensor as updated data. The nonvolatile memory transmits the temperature data stored in the buffer to the memory controller in response to a second instruction transmitted from the memory controller.

Hereinafter, embodiments will be described with reference to the drawings. In the following description, common reference signs are given to elements that have the same functions and configurations.

In the following description, the same reference signs are given to elements that have substantially the same functions and configurations. When elements that have similar configurations are distinguished from each other, different characters or numerals are suffixed to the same signs.

### 1. First Embodiment

### 1.1 Configuration

Hereinafter, a memory system including a nonvolatile memory will be described.

### 1.1.1 Memory System

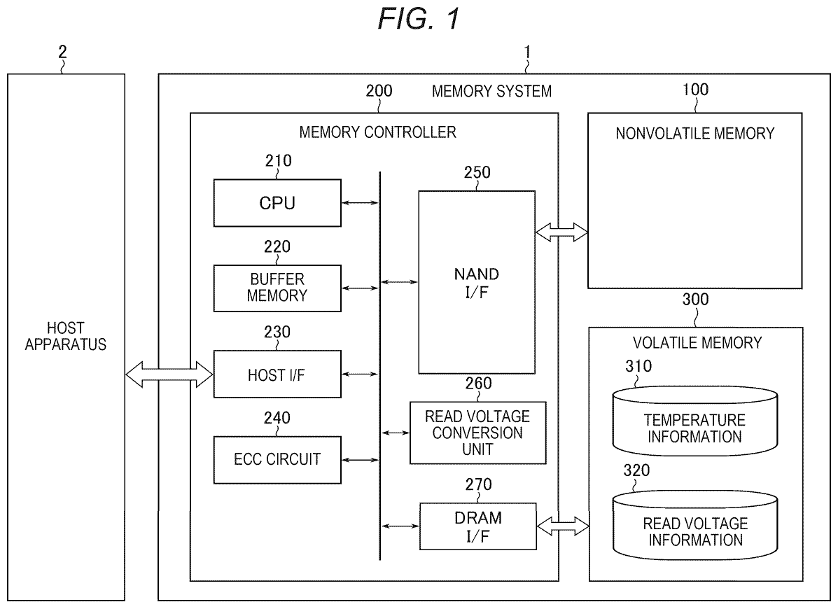

First, a configuration including the memory system will be described with reference to FIG. 1. FIG. 1 is a block diagram illustrating an example of a configuration including a memory system and a host apparatus according to a first embodiment.

A memory system 1 includes a nonvolatile memory 100, a memory controller 200, and a volatile memory 300. The nonvolatile memory 100, the memory controller 200, and the volatile memory 300 may be combined to configure, for example, a single semiconductor device. The memory system 1 is, for example, a solid state drive (SSD) or an SD™ card. The memory system 1 is connected to an external host apparatus 2. The memory system 1 stores data transmitted from the host apparatus 2. The memory system 1 reads data to the host apparatus 2.

The nonvolatile memory 100 is, for example, a semiconductor memory configured to store data in a nonvolatile manner. The semiconductor memory is, for example, a NAND flash memory. The nonvolatile memory 100 is configured to operate in response to a command from the memory controller 200.

The memory controller 200 is configured with, for example, an integrated circuit such as a system-on-a-chip (SoC). The memory controller 200 receives a command from the host apparatus 2. The memory controller 200 controls the nonvolatile memory 100 in response to the received command. For example, the memory controller 200 reads data commanded to be read from the host apparatus 2 from the nonvolatile memory 100 in response to a read command received from the host apparatus 2. The memory controller 200 transmits the data read from the nonvolatile memory 100 to the host apparatus 2. For example, the memory controller 200 writes data commanded to be written on the nonvolatile memory 100 in response to a write command received from the host apparatus 2.

The volatile memory 300 is, for example, a dynamic random access memory (DRAM). The volatile memory 300 stores firmware for managing the nonvolatile memory 100 and various types of management information. The volatile memory 300 stores, for example, temperature information 310 and read voltage information 320. In the temperature information 310, for example, a latest temperature measured in the nonvolatile memory 100 is stored. The read voltage information 320 is information for reading data from the nonvolatile memory 100. The read voltage information 320 includes, for example, information regarding a read voltage used for a read operation in the nonvolatile memory 100. As will be described below, an optimum read voltage varies depending on a temperature of the nonvolatile memory 100. The read voltage information 320 includes an optimum read voltage at the latest temperature of the nonvolatile memory 100 in addition to a regular read voltage. The read voltage information 320 may include, for example, a conversion formula or a conversion table for calculating an optimum read voltage corresponding to a temperature instead of including the optimum read voltage at the latest temperature.

### 1.1.2 Memory Controller

The memory controller 200 includes a processor (CPU) 210 (also referred to herein as “processor(s),” “processing circuits,” and/or “processing systems”), a buffer memory 220, a host interface circuit (host I/F) 230, an ECC circuit 240, a NAND interface circuit (NAND I/F) 250, a read voltage converter 260, and a DRAM interface circuit (DRAM I/F) 270. A function of each unit in the memory controller 200 can be implemented by dedicated hardware, a processor executing a program (firmware), or a combination thereof.

The processor 210 executes an operation of the entire memory controller 200 using a program stored in a read only memory (ROM) in the memory controller 200. The processor 210 issues, for example, commands for giving an instruction to execute various processes including writing, reading, and erasing of data on the nonvolatile memory 100.

The buffer memory 220 is, for example, a static random access memory (SRAM). The buffer memory 220 temporarily stores data read from the nonvolatile memory 100 by the memory controller 200, write data received from the host apparatus 2, and the like.

The host interface circuit 230 is connected to the host apparatus 2 via a host bus. The host interface circuit 230 is in charge of communication between the memory controller 200 and the host apparatus 2. The host bus is, for example, a bus conforming with an SD™ interface, a serial attached small computer system interface (SCSI) (SAS), a serial advanced technology attachment (ATA) (SATA), or a peripheral component interconnect express (PCIe), or the like.

The ECC circuit 240 executes error detection and error correction processes on data stored in the nonvolatile memory 100. More specifically, the ECC circuit 240 generates an error correction code during writing of data and assigns the error correction code to write data. The error correction code is, for example, hard decision decoding code such as a Bose-Chaudhuri-Hocquenghem code or Reed-Solomon (RS) code or a soft decision decoding code such as a low-density parity-check (LDPC) code. The ECC circuit 240 decodes the error correction code during a data read operation and detects whether there is an error bit (fail bit). The ECC circuit 240 identifies a location of the error bit and corrects an error when the error bit is detected.

The NAND interface circuit 250 is connected to the nonvolatile memory 100 by a NAND bus. The NAND interface circuit 250 executes communication in conformity with a NAND interface standard. Various signals based on the NAND interface standard will be described below. The NAND interface circuit 250 is in charge of communication with the nonvolatile memory 100. The NAND interface circuit 250 transmits data, a command, an address to the nonvolatile memory 100 in response to an instruction of the processor 210. The command is a signal for controlling the entire nonvolatile memory 100. The data includes read data and write data.

The read voltage converter 260 calculates, for example, an optimum read voltage at a latest temperature. The read voltage converter 260 can be implemented as a processing circuit including at least one processor and/or memory. For example, the read voltage converter 260 executes the calculation based on the temperature information 310 and the conversion formula or the conversion table stored in the volatile memory 300. The conversion formula or the conversion table may be stored in the memory controller 200 or may be stored in the volatile memory 300. For example, the read voltage converter 260 updates the read voltage information 320 based on a result of the above calculation. For example, when the read voltage information 320 includes a conversion formula or a conversion table for calculating an optimum read voltage corresponding to a temperature and the memory controller 200 gives (e.g., provides, transmits) a read operation, the read voltage converter 260 may execute the calculation. In the above configuration, the optimum read voltage is applied to the read operation in the nonvolatile memory 100.

The DRAM interface circuit 270 is connected to the volatile memory 300. The DRAM interface circuit 270 is in charge of communication between the memory controller 200 and the volatile memory 300. The DRAM interface circuit 270 executes communication in conformity with a DRAM interface standard.

### 1.1.3 Nonvolatile Memory

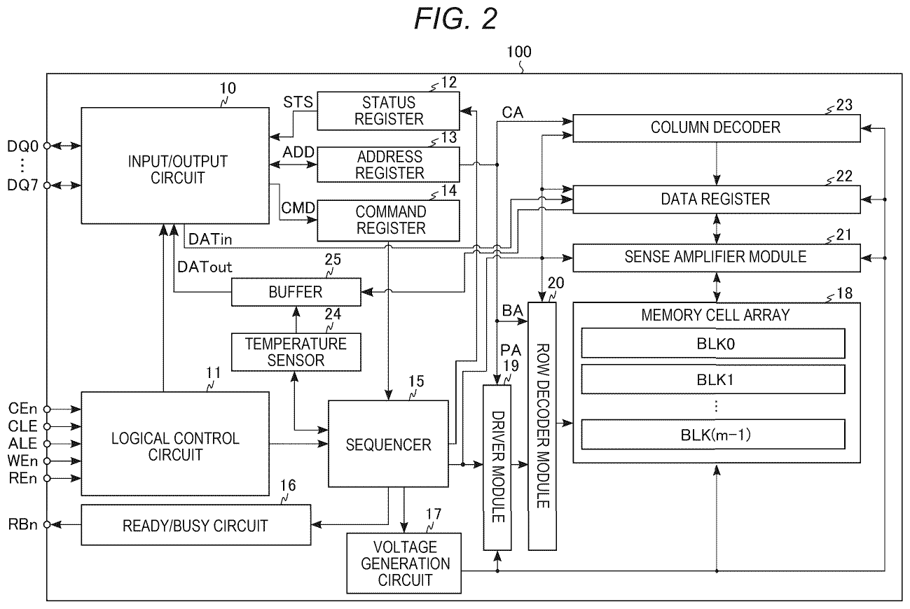

Next, a configuration of the nonvolatile memory 100 will be described with reference to FIG. 2. FIG. 2 is a block diagram illustrating an example of a configuration of a nonvolatile memory according to the first embodiment.

The nonvolatile memory 100 includes, for example, an input/output circuit 10, a logical control circuit 11, a status register 12, an address register 13, a command register 14, a sequencer 15, a ready/busy circuit 16, a voltage generation circuit 17, a memory cell array 18, a driver module 19, a row decoder module 20, a sense amplifier module 21, a data register 22, a column decoder 23, a temperature sensor 24, and a buffer 25.

Communication based on the NAND interface standard between the nonvolatile memory 100 and the memory controller 200 includes, for example, signals DQ[7:0], CEn, CLE, ALE, WEn, REn, and RBn.

The signal DQ[7:0] is, for example, a signal with an 8-bit width. The signal DQ[7:0] includes data DAT, an address ADD, and a command CMD. The data DAT includes data DATin input from the memory controller 200 and data DATout output to the memory controller 200.

The signal CEn is a chip enable signal. The signal CEn is a signal for enabling a chip. The signal CLE is a command latch enable signal. The signal CLE is used to notify the nonvolatile memory 100 that the signal DQ transmitted to the nonvolatile memory 100 is a command while the signal CLE is in a “high (H)” level. The signal ALE is an address latch enable signal. The signal ALE is used to notify the nonvolatile memory 100 that the signal DQ transmitted to the nonvolatile memory 100 is an address while the signal ALE is in the “H” level. The signal WEn is a write enable signal. The signal WEn is used to instruct the nonvolatile memory 100 to capture the signal DQ. The signal REn is a read enable signal. The signal REn is used to instruct the nonvolatile memory 100 to output the signal DQ. The signal RBn is a ready/busy signal. The signal RBn indicates whether the nonvolatile memory 100 is in a ready state or a busy state. The ready state is a state in which a command from the outside is received. The busy state is a state in which a command from the outside is not received.

The input/output circuit 10 controls an input and an output of the signal DQ[7:0] between the nonvolatile memory 100 and the memory controller 200. The input/output circuit 10 transmits the data DAT (write data) received from the memory controller 200 to the data register 22. The input/output circuit 10 transmits the address ADD received from the memory controller 200 to the address register 13. The input/output circuit 10 transmits the command CMD received from the memory controller 200 to the command register 14. The input/output circuit 10 transmits status information STS received from the status register 12, the data DAT (read data) received from the data register 22, the address ADD received from the address register 13, or the like to the memory controller 200.

The logical control circuit 11 receives, for example, the chip enable signal CEn, the command latch enable signal CLE, the address latch enable signal ALE, the write enable signal WEn, and the read enable signal REn from the memory controller 200. The logical control circuit 11 controls the input/output circuit 10 and the sequencer 15 in accordance with a signal received from the memory controller 200.

The status register 12 temporarily stores, for example, the status information STS received from the sequencer 15 in each of a write operation, a read operation, and an erase operation. The status information STS includes, for example, information used to notify the memory controller 200 whether the write operation, the read operation, the erase operation, or the like normally ends.

The address register 13 temporarily stores the address ADD received from the input/output circuit 10. The address ADD can include, for example, a page address PA, a block address BA, and a column address CA. For example, the address register 13 transmits the page address PA to the driver module 19, transmits the block address BA to the row decoder module 20, and transmits the column address CA to the column decoder 23.

The command register 14 temporarily stores the command CMD received from the input/output circuit 10. The command CMD is associated with an operation that can be executed by the nonvolatile memory 100. The command CMD stored by the command register 14 is referred to by the sequencer 15.

The sequencer 15 controls an operation of the entire nonvolatile memory 100. For example, the sequencer 15 can control the status register 12, the ready/busy circuit 16, the voltage generation circuit 17, the driver module 19, the row decoder module 20, the sense amplifier module 21, the data register 22, the column decoder 23, and the temperature sensor 24. The sequencer 15 executes a write operation, a read operation, an erase operation, and the like in response to the command CMD stored by the command register 14.

The ready/busy circuit 16 generates the ready/busy signal RBn based on an operation state of the sequencer 15. The ready/busy circuit 16 transmits the generated ready/busy signal RBn to the memory controller 200.

The voltage generation circuit 17 generates a voltage necessary in the write operation, the read operation, the erase operation, or the like under the control of the sequencer 15. The voltage generation circuit 17 supplies the generated voltage to the memory cell array 18, the driver module 19, the sense amplifier module 21, the data register 22, the column decoder 23, and the like.

The memory cell array 18 includes a plurality of blocks BLK (BLK0, BLK1, . . . and BLK(m−1)). Here, m is an integer of 2 or more. The blocks BLK are a set including a plurality of memory cell transistors that each store data in a nonvolatile manner. The blocks BLK are used as, for example, units of erasure of data. That is, the data stored by the plurality of memory cell transistors in the same block BLK can be erased collectively. Each of the memory cell transistors is associated with one word line and one bit line.

The driver module 19 generates a voltage used for a read operation, a write operation, an erase operation, or the like and applies the generated voltage to the row decoder module 20. Specifically, the driver module 19 and the row decoder module 20 are connected by a plurality of signal lines. The driver module 19 applies a plurality of types of voltages set for the read operation, the write operation, the erase operation, and the like to each of the plurality of signal lines based on the page address PA.

The row decoder module 20 is connected between the plurality of signal lines connected to the driver module 19 and a plurality of wirings provided respectively in the plurality of blocks BLK in the memory cell array 18. The row decoder module 20 selects one block BLK in the memory cell array 18 based on the block address BA. For example, the row decoder module 20 transmits the voltage applied to each of the plurality of signal lines by the driver module 19 to a word line or the like in the selected block BLK.

The sense amplifier module 21 determines data stored in the memory cell transistor based on a voltage of the bit line during a read operation. Then, the sense amplifier module 21 transmits a determination result as read data to the data register 22. The sense amplifier module 21 applies a voltage to each bit line in accordance with write data received from the data register 22 during a write operation.

The data register 22 includes a plurality of latch circuits. The plurality of latch circuits can store write data, read data, or the like. The data register 22 temporarily stores write data (DATin) received from the input/output circuit 10 and transmits the write data to the sense amplifier module 21 during a write operation. The data register 22 temporarily stores read data (DATout) received from the sense amplifier module 21 and transmits the read data to the input/output circuit 10 during a read operation. For example, the data register 22 transmits the data DATout to the input/output circuit 10 via the buffer 25. Between the input/output circuit 10 and the data register 22, the data DATin and the data DATout are each connected via eight data buses.

For example, the column decoder 23 decodes the column address CA in each of a write operation, a read operation, and an erase operation. The column decoder 23 selects a latch circuit in the data register 22 in accordance with a decoding result.

The temperature sensor 24 executes temperature measurement of the nonvolatile memory 100 under the control of the sequencer 15. The temperature sensor 24 transmits data (temperature data) capable of identifying the measured temperature to the buffer 25. The temperature data includes a temperature.

The buffer 25 temporarily stores the temperature data received from the temperature sensor 24. The buffer 25 transmits the stored temperature data as the data DATout to the input/output circuit 10, for example, when the temperature measurement is executed under the control of the sequencer 15. The buffer 25 transmits the data DATout to the input/output circuit 10 when the read data (the data DATout) is received from the sense amplifier module 21. The buffer 25 can transmit data in which the temperature data and the read data continue as the data DATout to the input/output circuit 10 when the temperature data is stored and the read data is received from the sense amplifier module 21.

### 1.1.4 Memory Cell Array

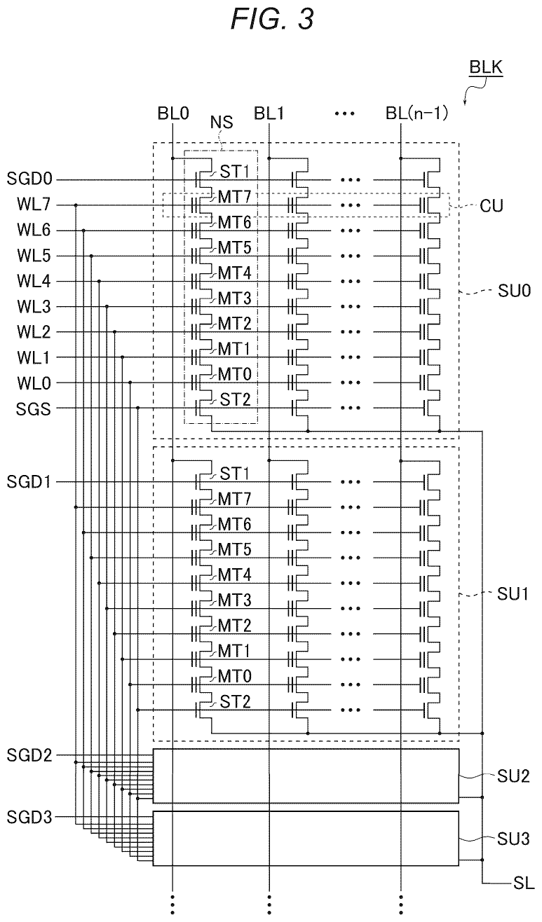

Next, a configuration of the memory cell array 18 in the nonvolatile memory 100 according to the first embodiment will be described with reference to FIG. 3. FIG. 3 is a circuit diagram illustrating an example of a circuit configuration of a memory cell array in the nonvolatile memory according to the first embodiment. FIG. 3 illustrates an example of a circuit diagram of one block BLK in the memory cell array 18.

The block BLK includes, for example, four string units SU0 to SU3. Since configurations of the string units SU2 and SU3 are as configurations of the string units SU0 and SU1, the configurations of the string units SU2 and SU3 are briefly illustrated in FIG. 3. In the following description, when the string units SU0 to SU3 are not distinguished from each other, the string units SU0 to SU3 are simply referred to as the string units SU.

Each string unit SU includes a plurality of NAND strings NS.

Each NAND string NS includes, for example, eight memory cell transistors MT (MT0 to MT7) and select transistors ST1 and ST2. The number of memory cell transistors MT in the NAND string NS is not limited. Each memory cell transistor MT includes a stacked gate including a control gate and a charge storage layer. In each NAND string NS, the memory cell transistors MT are connected in series between the select transistors ST1 and ST2.

In each block BLK, the gates of the select transistors ST1 of the string units SU0 to SU3 are connected to select gate lines SGD0 to SGD3, respectively. In the following description, when the select gate lines SGD0 to SGD3 are not distinguished from each other, the select gate lines SGD0 to SGD3 are simply referred to as the select gate lines SGD. The gates of the select transistors ST2 of all the string units SU in each block BLK are commonly connected to a select gate line SGS. Control gates of the memory cell transistors MT0 to MT7 in the same block BLK are connected to word lines WL0 to WL7, respectively. That is, the word line WL at the same address is commonly connected to all the string units SU in the same block BLK, and the select gate line SGS is commonly connected to all the string units SU in the same block BLK. On the other hand, the select gate lines SGD are connected to only one of the string units SU in the same block BLK.

The other end of the select transistor ST1 of the NAND string NS at the same row among the NAND strings NS arrayed in a matrix configuration in the memory cell array 18 is connected to one of n bit lines BL (BL0 to BL(n−1)). Here, n is an integer of 2 or more. The bit lines BL are commonly connected to the NAND string NS at the same column over the plurality of blocks BLK.

The other end of the select transistor ST2 is connected to a source line SL. The source line SL is commonly connected to the plurality of NAND strings NS over the plurality of blocks BLK.

As described above, for example, data is erased collectively in the memory cell transistors MT in the same block BLK. On the other hand, a read operation and a write operation for data can be executed collectively on the plurality of memory cell transistors MT commonly connected to one word line WL in one string unit SU of one block BLK. A set including the plurality of memory cell transistors MT sharing the word line WL in one string unit SU is referred to as, for example, a cell unit CU. That is, the cell unit CU is a set including a plurality of memory cell transistors MT on which a write operation or a read operation is executed collectively. For example, storage capacity of the cell unit CU including the plurality of memory cell transistors MT each storing 1-bit data is defined as “1-page data”. The 1-page data is used as, for example, units of reading of data. The cell unit CU can have storage capacity of 2-page data or more in accordance with the number of bits of data stored in the memory cell transistor MT.

### 1.1.5 Threshold Voltage Distribution of Memory Cell Transistor

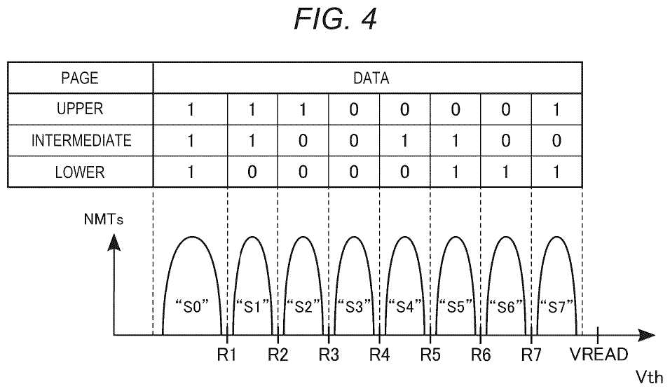

A threshold voltage distribution of the memory cell transistors in the memory system 1 according to the first embodiment will be described with reference to FIG. 4. FIG. 4 is a schematic diagram illustrating an example of a threshold voltage distribution of memory cell transistors in the memory system according to the first embodiment. In the threshold voltage distribution illustrated in FIG. 4, the vertical axis corresponds to the number NMTs of memory cell transistors MT and the horizontal axis corresponds to a threshold voltage Vth of the memory cell transistor MT.

As illustrated in FIG. 4, in the memory system 1 according to the first embodiment, for example, the threshold voltage distribution has eight states in accordance with the threshold voltage of the plurality of memory cell transistors MT in the one cell unit CU.

Hereinafter, the eight states are referred to as a state “S0”, a state “S1”, a state “S2”, a state “S3”, a state “S4”, a state “S5”, a state “S6”, and a state “S7” in order from the lowest threshold voltage.

To distinguish the eight states “S0” to “S7” from each other, seven read voltages R1, R2, R3, R4, R5, R6, and R7 are used. To turn all the memory cell transistors MT on regardless of data to be stored, a voltage VREAD is used. The read voltages R1 to R7 and the voltage VREAD are applied to the gates of the memory cell transistors MT. A relationship among the read voltages R1 to R7 and the voltage VREAD is R1<R2<R3<R4<R5<R6<R7<VREAD.

A threshold voltage of the memory cell transistor MT in the state “S0” is less than the read voltage R1. A threshold voltage of the memory cell transistor MT in the state “S1” is equal to or greater than the read voltage R1 and less than the read voltage R2. A threshold voltage of the memory cell transistor MT in the state “S2” is equal to or greater than the read voltage R2 and less than the read voltage R3. A threshold voltage of the memory cell transistor MT in the state “S3” is equal to or greater than the read voltage R3 and less than the read voltage R4. A threshold voltage of the memory cell transistor MT in the state “S4” is equal to or greater than the read voltage R4 and less than the read voltage R5. A threshold voltage of the memory cell transistor MT in the state “S5” is equal to or greater than the read voltage R5 and less than the read voltage R6. A threshold voltage of the memory cell transistor MT in the state “S6” is equal to or greater than the read voltage R6 and less than the read voltage R7. A threshold voltage of the memory cell transistor MT in the state “S7” is equal to or greater than the read voltage R7 and less than the voltage VREAD.

When the read voltage R1 is applied to the gates, the memory cell transistors MT belonging to the state “S0” are turned on, and the memory cell transistors MT belonging to the states “S1” to “S7” are turned off. When the read voltage R2 is applied to the gates, the memory cell transistors MT belonging to the states “S0” and “S1” are turned on, and the memory cell transistors MT belonging to the states “S2” to “S7” are turned off. When the read voltage R3 is applied to the gates, the memory cell transistors MT belonging to the states “S0” to “S2” are turned on, and the memory cell transistors MT belonging to the states “S3” to “S7” are turned off. When the read voltage R4 is applied to the gates, the memory cell transistors MT belonging to the states “S0” to “S3” are turned on, and the memory cell transistors MT belonging to the states “S4” to “S7” are turned off. When the read voltage R5 is applied to the gates, the memory cell transistors MT belonging to the states “S0” to “S4” are turned on, and the memory cell transistors MT belonging to the states “S5” to “S7” are turned off. When the read voltage R6 is applied to the gates, the memory cell transistors MT belonging to the states “S0” to “S5” are turned on, and the memory cell transistors MT belonging to the states “S6” and “S7” are turned off. When the read voltage R7 is applied to the gates, the memory cell transistors MT belonging to the states “S0” to “S6” are turned on, and the memory cell transistors MT belonging to the state “S7” are turned off. When the voltage VREAD is applied to the gates, the memory cell transistors MT belonging to all the states “S0”to “S7”are turned on.

Different 3-bit data is assigned to each of the eight states described above. Examples of data of “an upper bit, an intermediate bit, and a lower bit” assigned to each of the eight states are as follows.
State “S0”: “1, 1, 1” data
State “S1”: “1, 1, 0” data
State “S2”: “1, 0, 0” data
State “S3”: “0, 0, 0” data
State “S4”: “0, 1, 0” data
State “S5”: “0, 1, 1” data
State “S6”: “0, 0, 1” data
State “S7”: “1, 0, 1” data

When the data is assigned in this way, 1-page data (lower page data) with lower bits is confirmed by a read operation using the read voltages R1 and R5. 1-page data (intermediate page data) with intermediate bits is confirmed by a read operation using the read voltages R2, R4, and R6. 1-page data (upper page data) with upper bits is confirmed by a read operation using the read voltages R3 and R7. That is, the lower page data, the intermediate page data, and the upper page data are confirmed by read operations using two types, three types, and two types read voltages, respectively. The read operations of confirming the lower page data, the intermediate page data, and the upper page data are referred to as a lower page read, an intermediate page read, and an upper page read, respectively.

### 1.1.6 Temperature Dependency of Threshold Voltage Distribution

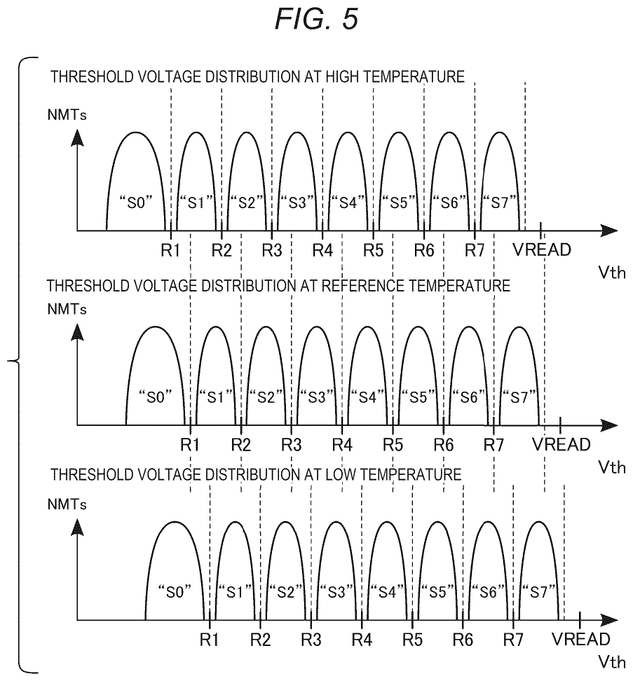

Next, temperature dependency of the threshold voltage distribution of the memory cell transistors in the memory system 1 according to the first embodiment will be described with reference to FIG. 5. FIG. 5 is a schematic diagram illustrating an example of the temperature dependency of the threshold voltage distribution of the memory cell transistors in the memory system according to the first embodiment. FIG. 5 illustrates threshold voltage distributions of the memory cell transistors at a reference temperature, a temperature higher than the reference temperature (a high temperature in FIG. 5), and a temperature lower than the reference temperature (a low temperature in FIG. 5) using the reference temperature as a standard.

A threshold voltage distribution of the memory cell transistors varies depending on a temperature of the nonvolatile memory 100. When the threshold voltage distribution of the memory cell transistors at the reference temperature is a standard, the threshold voltage distribution at the high temperature varies to, for example, a lower voltage on the whole. Accordingly, the read voltages R1 to R7 and the voltage VREAD at the high temperature are lower than the read voltages R1 to R7 and the voltage VREAD at the reference temperature. When the threshold voltage distribution of the memory cell transistors at the reference temperature is a standard, the threshold voltage distribution at the low temperature varies to, for example, a higher voltage on the whole. Accordingly, the read voltages R1 to R7 and the voltage VREAD at the low temperature are higher than the read voltages R1 to R7 and the voltage VREAD at the reference temperature. As described above, the optimum read voltages R1 to R7 vary depending on the temperature.

In the first embodiment, the nonvolatile memory 100 transmits a latest temperature (temperature data) measured by the temperature sensor 24 as the data DATout to the memory controller 200. Accordingly, the read voltage converter 260 of the memory controller 200 can calculate the read voltages R1 to R7 at the latest temperature. The read voltages R1 to R7 calculated in this way can be read as optimum read voltages at the latest temperature and stored in the read voltage information 320.

### 1.2 Operation

An operation of the memory system 1 according to the first embodiment will be described.

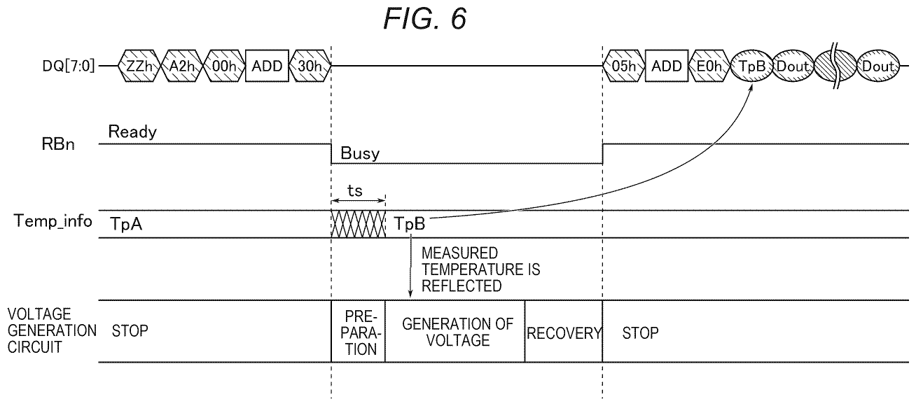

Hereinafter, an operation example when a read operation is executed in the nonvolatile memory 100 will be described with reference to FIG. 6. FIG. 6 is a schematic diagram illustrating an example of a command sequence of a read operation in the memory system according to the first embodiment. FIG. 6 illustrates an example in which temperature data of the nonvolatile memory 100 is transmitted as the data DATout to the memory controller 200 by the signal DQ[7:0] during the read operation. The read operation in the operation of the memory system 1 according to the first embodiment may be a read operation executed in response to a command issued by the memory controller 200 based on a command of the host apparatus 2 or may be a read operation executed in response to a command issued by the memory controller 200 irrespective of a command of the host apparatus 2.

When the read operation is executed in the operation example according to the first embodiment, the memory controller 200 transmits commands “ZZh”, “A2h”, “00h”, “ADD”, and “30h” in this order to the nonvolatile memory 100. The command “ZZh” is, for example, a command for giving an instruction to update the temperature information 310 using the latest temperature measured by the temperature sensor 24 during the read operation. The command “A2h” is a command for designating the read operation. That is, the command “A2h” is, for example, a command for designating which read operation is executed among the lower page read, the intermediate page read, and the upper page read. The command “00h” is, for example, a command for delivering an input of the address ADD after this command. The address ADD designated after the command “00h” is transmitted to designate reading target memory cell transistors MT. The address ADD includes, for example, a column address CA and a page address PA. The address “ADD” may be transmitted at a plurality of cycles. The command “30h” is, for example, a command for giving an instruction to start the read operation. When the nonvolatile memory 100 receives the command “30h”, the sequencer 15 causes the nonvolatile memory 100 to transition from the ready state to the busy state. The sequencer 15 starts the read operation designated with the commands “A2h”, “00h”, and “ADD” (e.g., a first instruction transmitted from the memory controller for initiating the first operation, such as a read operation command sequence).

When the sequencer 15 starts the read operation, for example, the sequencer 15 starts up the temperature sensor 24. Accordingly, the temperature sensor 24 measures a temperature of the nonvolatile memory 100 when a period ts passes from the start of the read operation. The period ts is a period from start to completion of the temperature measurement by the temperature sensor 24. When the period ts passes, the temperature sensor 24 confirms the temperature of the nonvolatile memory 100 and completes the measurement. In the example of FIG. 6, temperature data Temp_info stored in the buffer 25 is a temperature TpA before the read operation starts. After the period ts passes from the start of the read operation, the temperature data Temp_info is regarded as a latest temperature TpB measured by the temperature sensor 24 during the period ts.

When the sequencer 15 starts the read operation, the sequencer 15 instructs the voltage generation circuit 17 to prepare for generation of a read voltage. Accordingly, the voltage generation circuit 17 causes a state to transition from a stop sate (Stop in FIG. 6) to a state (Preparation in FIG. 6) for preparation of generation of the read voltage. When the preparation of the generation of the read voltage ends, the voltage generation circuit 17 causes the state to transition to a state (Generation of voltage in FIG. 6) in which a voltage can be generated. Accordingly, the voltage generation circuit 17 starts generating the read voltage. The read voltage is generated by the voltage generation circuit 17, for example, after the period ts passes. Accordingly, in the generation of the read voltage, the sequencer 15 can control the voltage generation circuit 17 such that the read voltage corresponding to the latest temperature TpB measured by the temperature sensor 24 is generated. At this time, the sequencer 15 calculates the read voltage corresponding to the temperature TpB, for example, using a calculation mechanism (not illustrated) in the nonvolatile memory 100. In this way, as illustrated in FIG. 6, the temperature measured by the temperature sensor 24 is reflected in the generation of the read voltage. Under the control of the sequencer 15, the generated read voltage is used to read data from the memory cell transistors MT corresponding to the designated address ADD. When the read operation ends, the voltage generation circuit 17 executes recovery. Accordingly, a voltage of each wiring in the nonvolatile memory 100 is regarded as, for example, a voltage VSS.

When the recovery ends, the voltage generation circuit 17 causes the state to transition to the stop state. The sequencer 15 transmits a read result read as described above to the data register 22. When the read result is transmitted to the data register 22, the sequencer 15 causes the nonvolatile memory 100 to transition from the busy state to the ready state. In this way, the read operation in the nonvolatile memory 100 ends.

When the read operation in the nonvolatile memory 100 ends, the memory controller 200 transmits commands “05h”, “ADD”, and “E0h” in this order to the nonvolatile memory 100. The command “05h” is, for example, a command for delivering an input of an address for designating data to be output among the data read through the read operation after this command. The address ADD designated after the command “05h” is transmitted to designate the memory cell transistors MT regarded as an output target of the read data to the memory controller 200. The command “E0h” is a command for designating start of an output of read data Dout regarded as an output target (e.g., a second instruction transmitted from the memory controller for retrieving the temperature data, such as a data output command sequence).

After the command “E0h” is transmitted, the nonvolatile memory 100 outputs the temperature data Temp_info (temperature TpB) to the memory controller 200 based on a command “ZZh” immediately before a command for designating the read operation. The nonvolatile memory 100 outputs the read data Dout regarded as the output target to the memory controller 200 based on the commands “05h”, “ADD”, and “E0h”. For example, the nonvolatile memory 100 continuously (e.g., transmits the temperature data and read data in a structured sequence without requiring a separate request for each data type, where the data may be output as part of a single transfer operation or in a manner that minimizes latency between transmissions) transmits the temperature data Temp_info and the read data Dout in this order.

Thereafter, the memory controller 200 updates the temperature information 310 based on the temperature data Temp_info. That is, the temperature information can be updated using the temperature data received from the nonvolatile memory and the memory controller 200 can provide an instruction to execute a read operation using a read voltage converted (e.g., adjusted from a default or previously used read voltage to a new read voltage value based on the most recent temperature data, where the conversion may involve applying a stored temperature-to-voltage mapping, performing a real-time computation, and/or selecting a precomputed value from a lookup table) based on the temperature information when an instruction to execute a read operation is given (e.g., provided, transmitted) to the nonvolatile memory. For example, based on the temperature data Temp_info, the memory controller 200 calculates the read voltage based on the latest temperature and updates the read voltage information 320.

Through the above operations, the read voltage that is based on the latest temperature acquired as described above can be applied in a subsequent read operation in the nonvolatile memory 100.

### 1.3 Advantages of First Embodiment

In the memory system 1 according to the first embodiment, reliability of the memory system can be improved. Hereinafter, advantages of the first embodiment will be described.

The memory system 1 according to the first embodiment includes the nonvolatile memory 100 and the memory controller 200. The nonvolatile memory 100 includes the plurality of memory cell transistors MT, the temperature sensor 24 configured to acquire the temperature data Temp_info through temperature measurement, and the buffer 25 configured to store the temperature data Temp_info. When the nonvolatile memory 100 executes a read operation in response to an instruction for the read operation transmitted from the memory controller 200, the temperature sensor 24 is configured to acquire the temperature data Temp_info of the nonvolatile memory 100 in the read operation. The buffer 25 is configured to store the temperature data Temp_info acquired by the temperature sensor 24 as updated data (e.g., latest data, most recent data, current data, recently acquired data). The nonvolatile memory 100 transmits the temperature data Temp_info stored in the buffer 25 to the memory controller 200 based on the command “ZZh” transmitted from the memory controller 200. With the above configuration, it is possible to acquire information regarding a temperature of the nonvolatile memory 100 at high frequency. Accordingly, it is possible to improve reliability of the memory system 1.

In addition, in the case of a comparative example in which a nonvolatile memory does not include a buffer configured to store temperature data, the nonvolatile memory transmits the temperature data in a temperature sensor to an input/output circuit under the control of a sequencer when an instruction to transmit the temperature data to the memory controller is received. At this time, for example, the temperature data is output to the memory controller via the temperature sensor, the sequencer, and the input/output circuit, which may cause delay of an output of the data. Accordingly, in the case of the comparative example, an operation speed may deteriorate due to the delay of the output of the temperature data.

In the comparative example, more specifically, when the temperature data is output in a read operation, for example, a command for outputting the temperature data acquired by the temperature sensor is transmitted from the memory controller to the nonvolatile memory after the read operation ends. Accordingly, in response to this command, the temperature data is output to the memory controller. Thereafter, a command for outputting the data read through the read operation is transmitted from the memory controller to the nonvolatile memory. Accordingly, the nonvolatile memory outputs the read data to the memory controller. In the above operation, in the comparative example, the nonvolatile memory does not include a buffer configured to store the temperature data. Therefore, until the temperature data is output after reception of the command for outputting the temperature data, a period for preparing an output has to be awaited. Accordingly, an operation may be delayed in some cases.

In the embodiment, however, during the read operation, the memory controller 200 transmits the command “ZZh” for giving an instruction to update the temperature information 310 immediately before the command “A2h” for giving an instruction for the read operation. For example, in the read operation, the temperature data Temp_info is acquired by the temperature sensor 24 and the temperature data Temp_info is stored in the buffer 25. When the read operation ends and the nonvolatile memory 100 receives the command “05h” or the like for outputting the data read through the read operation, the temperature data Temp_info stored in the buffer 25 is output along with the read data. In this way, since a period for preparing an output does not need to be awaited according to the embodiment, delay of an operation is inhibited. Accordingly, it is possible to acquire the temperature data at high frequency. When a subsequent read operation is executed, the read voltage based on the latest temperature data acquired at the high frequency can be applied. Therefore, it is possible to inhibit an increase in the number of fail bits during the read operation in the nonvolatile memory 100.

### 2. Second Embodiment

In the above-described first embodiment, as described in the example, the command for giving the instruction to update the temperature information using the latest temperature measured by the temperature sensor is transmitted before the command for designating the read operation, but an embodiment is not limited thereto. The command for giving the instruction to update the temperature information using the latest temperature measured by the temperature sensor may be transmitted to the nonvolatile memory 100 while the nonvolatile memory 100 executes the read operation.

Hereinafter, differences between a configuration and an operation of a memory system 1 according to the second embodiment and the configuration and the operation of the memory system according to the first embodiment will be described.

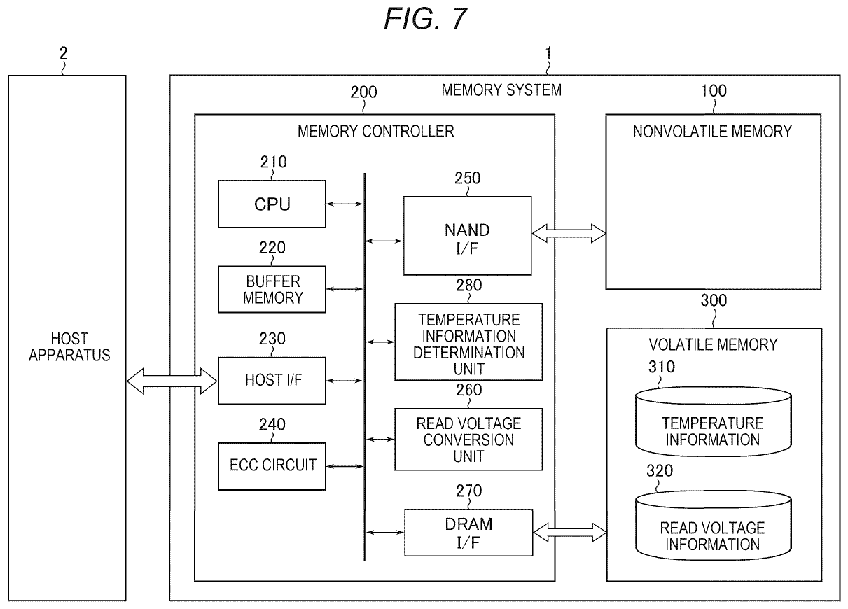

A configuration of the memory system 1 according to the second embodiment will be described with reference to FIG. 7. FIG. 7 is a block diagram illustrating an example of a configuration including a memory system and a host apparatus according to the second embodiment.

The memory controller 200 according to the second embodiment further includes a temperature information determinator 280. The temperature information determinator 280 can be implemented as a processing circuit including at least one processor and/or memory. The temperature information determinator 280 is configured to be able to determine whether the temperature sensor 24 is operating based on the temperature data Temp_info received from the nonvolatile memory 100. More specifically, the temperature sensor 24 of the nonvolatile memory 100 according to the second embodiment transmits data FFh indicating that an accurate temperature cannot be outputted (e.g., is not available for transmission, is unavailable for retrieval, is not available for transmission, cannot be retrieved) as the temperature data Temp_info to the buffer 25, for example, when an operation of the temperature sensor 24 starts. Accordingly, while the temperature sensor 24 is operating (while the temperature sensor 24 is in a “disable” state), the data FFh is stored as the temperature data Temp_info in the buffer 25. The nonvolatile memory 100 is configured to transmit the temperature data Temp_info when a temperature acquisition command is received from the memory controller 200. The temperature acquisition command is transmitted from the memory controller 200 to the nonvolatile memory 100 and is a command for acquiring a temperature of the nonvolatile memory 100. With the above configuration, when the memory controller 200 receives the data FFh based on the above command, the temperature information determinator 280 determines that the temperature sensor 24 cannot output an accurate temperature (e.g., is not available for transmission). That is, the temperature information determinator 280 determines that the temperature sensor 24 is operating. Based on the above command, it is determined that the temperature data Temp_info is a latest temperature when the temperature data Temp_info received by the memory controller 200 is not the data FFh (when the temperature sensor 24 is in an “enable” state and the temperature data Temp_info is a specific temperature).

An operation of the memory system 1 according to the second embodiment will be described.

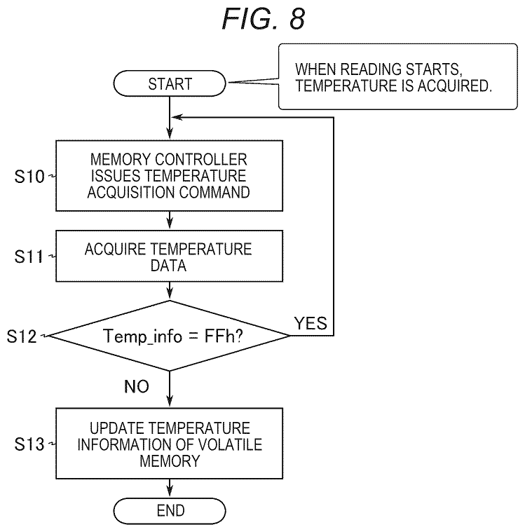

First, an operation example in the memory system 1 according to the second embodiment will be described with reference to FIG. 8. FIG. 8 is a flowchart illustrating an operation example in the memory system according to the second embodiment.

When a read operation in the nonvolatile memory 100 starts, the memory controller 200 issues the temperature acquisition command to the nonvolatile memory 100 in S10. Then, the process proceeds to S11.

In S11, the memory controller 200 acquires the temperature data Temp_info stored in the buffer 25. Then, the process proceeds to S12.

In S12, the temperature information determinator 280 of the memory controller 200 determines whether the acquired temperature data Temp_info is the data FFh (Temp_info =FFh?). When it is determined that the temperature data Temp_info is the data FFh (YES in S12), the process of S10 is executed again. When it is determined that the temperature data Temp_info is not the data FFh (NO in S12), the process proceeds to S13.

In this way, while the temperature data Temp_info is the data FFh (YES is regarded in S12), for example, the memory controller 200 repeatedly issues the temperature acquisition command until it is determined that the temperature data Temp_info is not the data FFh.

When it is determined that the temperature data Temp_info is not the data FFh (NO in S12), the temperature information 310 of the volatile memory 300 is updated based on the temperature data Temp_info in S13. For example, based on the temperature data Temp_info, the memory controller 200 calculates the read voltage based on the latest temperature and updates the read voltage information 320.

In this way, the acquisition of the temperature based on the temperature acquisition command ends. The acquisition of the temperature based on the temperature acquisition command and the read operation end independently. The memory controller 200 acquires the temperature, for example, before the read operation ends.

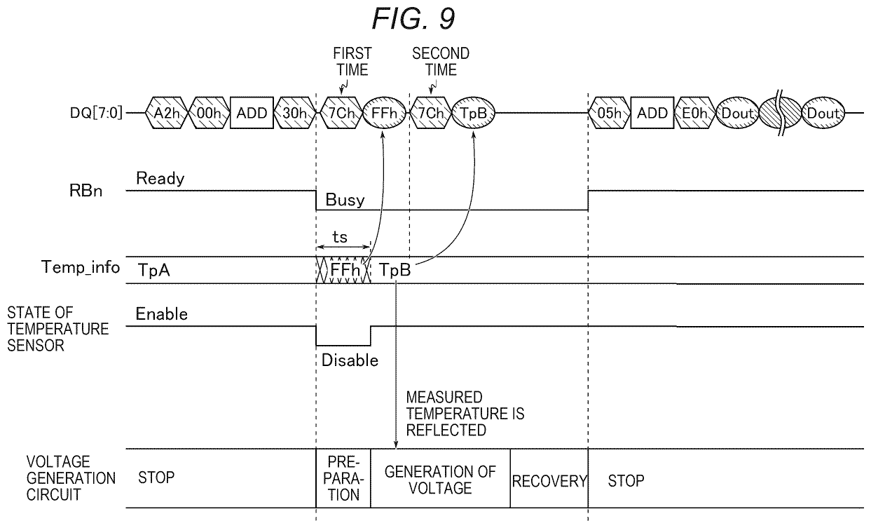

Next, an operation example in the memory system 1 according to the second embodiment will be further described with reference to FIG. 9. FIG. 9 is a schematic diagram illustrating an example of a command sequence of the operation example in the memory system according to the second embodiment.

In FIG. 9, the operation example during a read operation on the nonvolatile memory 100 will be described. Hereinafter, differences from the command sequence of the operation according to the first embodiment will be mainly described.

When a read operation in the operation example according to the second embodiment is executed, the memory controller 200 transmits the commands “A2h”, “00h”, “ADD”, and “30h” to the nonvolatile memory 100 in this order.

When the sequencer 15 starts the read operation, the memory controller 200 transmits a command “7Ch” to the nonvolatile memory 100. The command “7Ch” is a temperature acquisition command. In the period ts after start of the read operation, the temperature data Temp_info is the data FFh indicating that the temperature sensor 24 cannot output an accurate temperature. Accordingly, the memory controller 200 transmits the command “7Ch” to the nonvolatile memory 100 again. In the example of FIG. 9, when the second command “7Ch” is transmitted, the temperature sensor 24 is in a state in which the temperature measurement is completed. The buffer 25 stores the temperature TpB as the temperature data Temp_info from the temperature sensor 24. Therefore, the nonvolatile memory 100 transmits the temperature data Temp_info (the temperature TpB) to the memory controller 200 based on the command “7Ch”. In this way, for example, while the read operation is executed (while the nonvolatile memory 100 is in a busy state), the memory controller 200 acquires the latest temperature.

The read data is transmitted to the memory controller 200 in response to the command “E0h” received from the memory controller 200 similarly to the command sequence of the operation according to the first embodiment except that the temperature data Temp_info is not output to the memory controller 200.

Through the above operation, the read voltage based on the latest temperature acquired as described above can also be applied in a subsequent read operation in the nonvolatile memory 100.

In the memory system 1 according to the second embodiment, like the memory system according to the first embodiment, it is also possible to acquire information regarding the temperature of the nonvolatile memory 100 at high frequency. Accordingly, it is possible to improve reliability of the memory system 1.

### 3. Third Embodiment

In the above-described second embodiment, as described in the example, until the nonvolatile memory 100 can acquire the accurate temperature after the start of the read operation, the memory controller 200 repeatedly issues the temperature acquisition command, but an embodiment is not limited thereto. The memory controller 200 may be configured to acquire the temperature data after a period until completion of the temperature measurement by the temperature sensor 24 passes.

Hereinafter, differences between a configuration and an operation of a memory system 1 according to the third embodiment and the configuration and the operation of the memory system according to the second embodiment will be described.

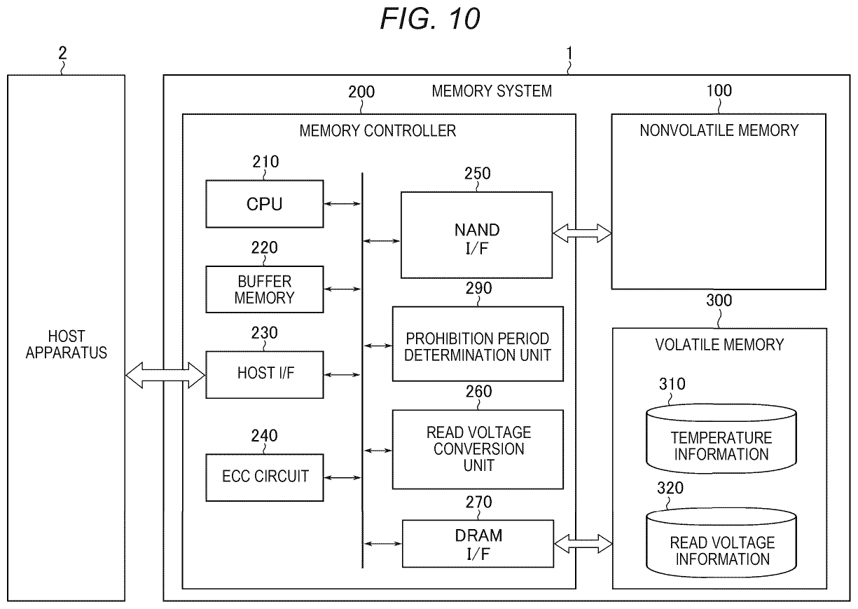

A configuration of the memory system 1 according to the third embodiment will be described with reference to FIG. 10. FIG. 10 is a block diagram illustrating an example of a configuration including a memory system and a host apparatus according to the third embodiment.

The memory controller 200 according to the third embodiment further includes a prohibition period determinator 290. The prohibition period determinator 290 is configured to be able to determine whether the temperature measurement by the temperature sensor 24 is completed when the nonvolatile memory 100 executes the read operation. The prohibition period determinator 290 determines whether the period ts in which the temperature measurement by the temperature sensor 24 starts and then ends passes. While the prohibition period determinator 290 determines that the period ts does not pass, the memory controller 200 does not issue the temperature acquisition command. When the prohibition period determinator 290 determines that the period ts passes, the memory controller 200 issues the temperature acquisition command. Accordingly, the memory controller 200 acquires a latest temperature from the nonvolatile memory 100 in accordance with the temperature data Temp_info.

An operation of the memory system 1 according to the third embodiment will be described.

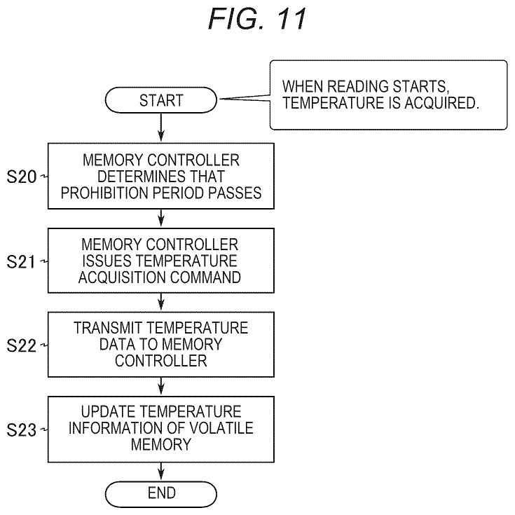

First, an operation example in the memory system 1 according to the third embodiment will be described with reference to FIG. 11. FIG. 11 is a flowchart illustrating the operation example in the memory system according to the third embodiment.

When the read operation starts in the nonvolatile memory 100, for example, the prohibition period determinator 290 starts determining whether the period ts passes.

In S20, the prohibition period determinator 290 determines that the read operation starts and then the period ts passes. Then, the process proceeds to S21.

In S21, the memory controller 200 issues the temperature acquisition command to the nonvolatile memory 100. Then, the process proceeds to S22.

In S22, the memory controller 200 acquires the temperature data Temp_info stored in the buffer 25. Then, the process proceeds to S23.

In S23, the temperature information 310 of the volatile memory 300 is updated based on the temperature data Temp_info. For example, based on the temperature data Temp_info, the memory controller 200 calculates a read voltage based on the latest temperature and updates the read voltage information 320.

In this way, the acquisition of the temperature in response to the temperature acquisition command ends.

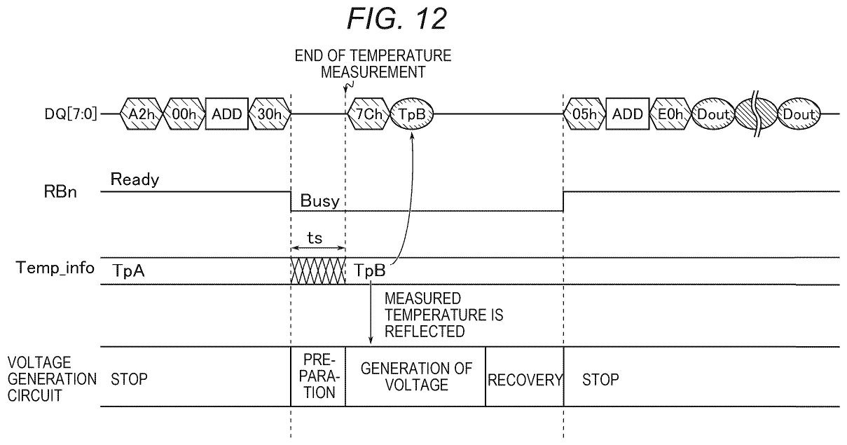

Next, an operation example in the memory system 1 according to the third embodiment will be further described with reference to FIG. 12. FIG. 12 is a schematic diagram illustrating an example of a command sequence of the operation example in the memory system according to the third embodiment.

In FIG. 12, the operation example during the read operation executed on the nonvolatile memory 100 will be described. Hereinafter, differences from the command sequence of the operations according to the second embodiment will be mainly described.

When the read operation starts in the operation example according to the third embodiment, the prohibition period determinator 290 starts determining whether the period ts passes.

When the prohibition period determinator 290 determines that the period ts passes, the memory controller 200 transmits the command “7Ch” to the nonvolatile memory 100. Accordingly, the nonvolatile memory 100 transmits the temperature data Temp_info (the temperature TpB) to the memory controller 200 in response to the command “7Ch”. In this way, the memory controller 200 acquires a latest temperature.

In the memory system 1 according to the third embodiment, like the memory system according to the first embodiment, it is also possible to acquire information regarding the temperature of the nonvolatile memory 100 at high frequency. Accordingly, it is possible to improve reliability of the memory system 1.

### 4. Fourth Embodiment

In the above-described first to third embodiments, as described in the example, the memory controller 200 is configured to acquire the temperature data during in the operation in the nonvolatile memory 100, but an embodiment is not limited thereto. The memory controller 200 may be configured to acquire temperature data, for example, when power of the nonvolatile memory 100 is shut off and the nonvolatile memory 100 is in a standby state, or the like.

Hereinafter, a configuration and an operation of the memory system 1 according to the fourth embodiment will be described.

First, a configuration of the memory system 1 according to the fourth embodiment will be described. Hereinafter, differences between a configuration of a memory system 1 according to the fourth embodiment and the configuration of the memory system 1 according to the first embodiment will be described.

In the fourth embodiment, the memory controller 200 is configured to transmit a temperature acquisition command to the nonvolatile memory 100 when a predetermined process is executed (e.g., a condition is satisfied where the nonvolatile memory undergoes a power-off process, standby process, power-on process, and/or recovery from standby state). The predetermined process is, for example, a process of shutting off power of the nonvolatile memory 100 (a power shutoff process and/or power-off process) or a process of causing the nonvolatile memory 100 to enter a standby state (a standby process). For example, a first condition is a condition that a power-off process of the nonvolatile memory 100, a standby process of the nonvolatile memory, a power-on process of the nonvolatile memory that is powered off, or a recovery process of the nonvolatile memory in a standby state is executed. The predetermined process may be, for example, a process of powering on the nonvolatile memory 100 or a process of recovering the nonvolatile memory 100 from the standby state.

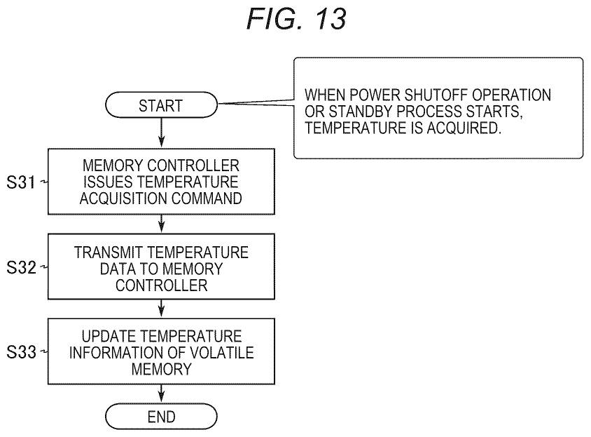

An operation of the memory system 1 according to the fourth embodiment will be described with reference to FIG. 13. FIG. 13 is a flowchart illustrating an operation example in the memory system according to the fourth embodiment.

When the power shutoff process or the standby process starts, the operation in the fourth embodiment starts.

In S31, for example, the memory controller 200 transmits the temperature acquisition command to the nonvolatile memory 100. Accordingly, the temperature sensor 24 starts the temperature measurement.

When the temperature measurement by the temperature sensor 24 ends, the nonvolatile memory 100 transmits the latest temperature as the temperature data Temp_info to the memory controller 200 in S32.

In S33, the temperature information 310 of the volatile memory 300 is updated based on the temperature data Temp_info. For example, based on the temperature data Temp_info, the memory controller 200 calculates a read voltage based on the latest temperature and updates the read voltage information 320.

In this way, when the power shutoff process or the standby process is executed, a temperature is acquired in response to the temperature acquisition command.

With the above configuration, after the power recovery or recovery from the standby, for example, the read voltage based on the latest temperature acquired as described above can be applied in a subsequent read operation in the nonvolatile memory 100.

In the fourth embodiment, like the memory system according to the first embodiment, it is also possible to acquire information regarding the temperature of the nonvolatile memory 100 at high frequency. Accordingly, it is possible to improve reliability of the memory system 1.

### 5. Fifth Embodiment

In the above-described first to fourth embodiments, as described in the example, the memory controller acquires the temperature of the nonvolatile memory during the operation or the process, but an embodiment is not limited thereto. The memory controller 200 may be configured to acquire the temperature data whenever a predetermined period passes.

Hereinafter, a configuration and an operation of the memory system 1 according to the fifth embodiment will be described.

First, a configuration of the memory system 1 according to the fifth embodiment will be described. Hereinafter, differences between a configuration of a memory system according to the fifth embodiment and the configuration of the memory system according to the fourth embodiment will be described.

In the fifth embodiment, for example, the memory controller 200 is configured to be able to count the period tp. Accordingly, whenever a predetermined period Ttp (a threshold of the period tp) passes, the memory controller 200 is configured to transmit the temperature acquisition command to the nonvolatile memory 100 (e.g., a condition is satisfied where the elapsed time reaches or exceeds Ttp). More specifically, the memory controller 200 is configured to be able to determine whether the period Ttp passes after start of the counting with the period tp set to 0, for example, in an operation of acquiring the temperature, as will described below. For example, when it is determined that the period tp becomes the period Ttp or more, the memory controller 200 transmits the temperature acquisition command to the nonvolatile memory 100. The memory controller 200 resets the period tp to 0 (e.g., clears the execution count and resumes counting from zero to track subsequent executions of the read operation until the next threshold Tnr is reached for triggering another temperature acquisition command). The memory controller 200 does not transmit the temperature acquisition command to the nonvolatile memory 100 when the period tp is less than the period Ttp.

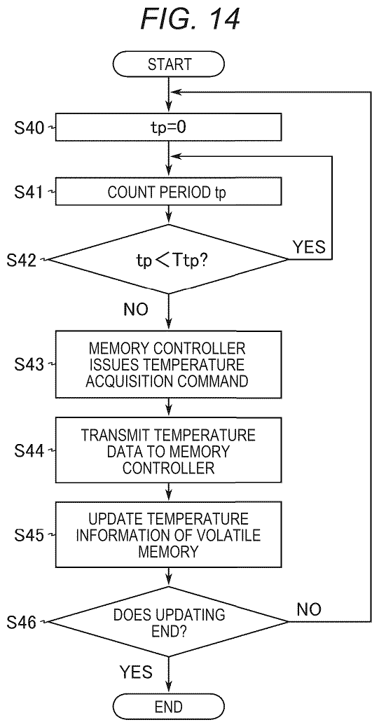

Next, an operation of acquiring a temperature in the memory system 1 according to the fifth embodiment will be described with reference to FIG. 14. FIG. 14 is a flowchart illustrating an operation example in a memory system according to the fifth embodiment.

When an operation of the memory system 1 according to the fifth embodiment starts, the memory controller 200 sets a period tp to 0 (tp=0) in S40. Then, the process proceeds to S41.

In S41, the memory controller 200 counts the period tp over time. Then, the process proceeds to step S42.

In S42, the memory controller 200 determines whether the period tp is less than a predetermined period Ttp. When the memory controller 200 determines that the period tp is less than the predetermined period Ttp (YES in S42), the process of S41 is executed again. When the memory controller 200 determines that the period tp is equal to or greater than the predetermined period Ttp (NO in S42), the process proceeds to S43.

In S43, the memory controller 200 transmits, for example, the temperature acquisition command to the nonvolatile memory 100. Accordingly, the temperature sensor 24 starts temperature measurement.

When the temperature measurement by the temperature sensor 24 ends, the nonvolatile memory 100 transmits latest temperature as the temperature data Temp_info to the memory controller 200 in S44. Then, the process proceeds to S45.

In S45, the temperature information 310 of the volatile memory 300 is updated based on the temperature data Temp_info. For example, based on the temperature data Temp_info, the memory controller 200 calculates a read voltage based on the latest temperature and updates the read voltage information 320. Then, the process proceeds to S46.

In S46, the memory controller 200 determines whether to end the updating of the temperature information 310. When the memory controller 200 determines not to end the updating of the temperature information 310 (NO in S46), the process of S40 is executed again. When the memory controller 200 determines to end the updating of the temperature information 310 (YES in S46), the process ends.

In this way, until it is determined to end the updating of the temperature information 310, the temperature information 310 is updated whenever the period Ttp passes.

With the above configuration, the read voltage based on the latest temperature can be applied when a subsequent read operation is executed.

According to the fifth embodiment, by acquiring the latest temperature based on the period tp, it is possible to acquire information regarding the temperature of the nonvolatile memory 100 at high frequency like the memory system according to the first embodiment. Accordingly, it is possible to improve reliability of the memory system 1.

### 6. Sixth Embodiment

In the above-described fifth embodiment, as described in the example, the memory controller is configured to acquire the temperature of the nonvolatile memory whenever the predetermined period passes, but an embodiment is not limited thereto. The memory controller 200 may be configured to acquire the temperature data based on the number of times the nonvolatile memory 100 executes the read operation (e.g., an execution count of a first operation).

Hereinafter, a configuration and an operation of the memory system 1 according to the sixth embodiment will be described.

First, a configuration of the memory system 1 according to the sixth embodiment will be described. Hereinafter, differences between a configuration of a memory system according to the sixth embodiment and the configuration of the memory system according to the fifth embodiment will be described.

In the sixth embodiment, for example, the memory controller 200 is configured to be able to count the number of times nr the nonvolatile memory 100 executes (starts) the read operation (e.g., a first execution count of a first operation). Accordingly, the memory controller 200 is configured to transmit the temperature acquisition command to the nonvolatile memory 100 whenever the read operation is executed by a predetermined number of times (e.g., execution count—condition is satisfied where the execution count of the read operation reaches or exceeds Tnr). More specifically, the memory controller 200 is configured to be able to start the counting with the number of times nr set to 0 and then determine whether the read operation is executed by a predetermined number of times Tnr (a threshold of the number of times nr) in an operation of acquiring a temperature, as will be described below. When the memory controller 200 determines that the number of times nr is equal to or greater than the number of times Tnr, the memory controller 200 transmits the temperature acquisition command to the nonvolatile memory 100. The memory controller 200 resets the number of times nr to 0 (e.g., clears the counted time and resumes counting from zero to continue monitoring whether the predetermined period Ttp has elapsed again for subsequent temperature acquisition operations). When the number of times nr is less than the number of times Tnr, the memory controller 200 does not transmit the temperature acquisition command to the nonvolatile memory 100.

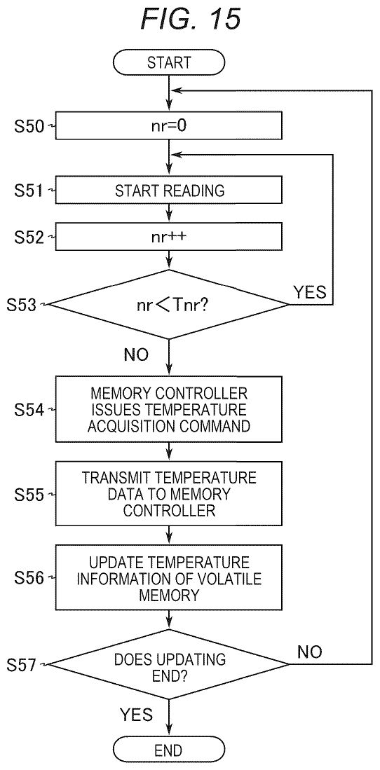

Next, an operation of the memory system 1 according to the sixth embodiment will be described with reference to FIG. 15. FIG. 15 is a flowchart illustrating an operation example in the memory system according to the sixth embodiment.

When the operation of the memory system 1 according to the sixth embodiment starts, the memory controller 200 sets the number of times nr to 0 (nr=0) in S50. Then, the process proceeds to S51.

In S51, the read operation of the nonvolatile memory 100 is started in response to an instruction of the memory controller 200. Then, the process proceeds to S52.

In S52, the memory controller 200 increments the number of times nr (nr++). Then, the process proceeds to S53.

In S53, the memory controller 200 determines whether the number of times nr is less than the number of times Tnr. When the memory controller 200 determines that the number of times nr is less than the number of times Tnr (YES in S53), the process of S51 is executed again. When the memory controller 200 determines that the number of times nr is equal to or greater than the number of times Tnr (NO in S53), the process proceeds to S54.

In S54, the memory controller 200 transmits, for example, the temperature acquisition command to the nonvolatile memory 100. Accordingly, the temperature sensor 24 starts the temperature measurement.

When the temperature measurement by the temperature sensor 24 ends, the nonvolatile memory 100 transmits the latest temperature as the temperature data Temp_info to the memory controller 200 in S55. Then, the process proceeds to S56.

In S56, the temperature information 310 of the volatile memory 300 is updated based on the temperature data Temp_info. For example, based on the temperature data Temp_info, the memory controller 200 calculates the read voltage based on the latest temperature and updates the read voltage information 320. Then, the process proceeds to S57.

In S57, the memory controller 200 determines whether to end the updating of the temperature information 310. When the memory controller 200 determines not to end the updating of the temperature information 310 (NO in S57), the process of S50 is executed again. When the memory controller 200 determines to end the updating of the temperature information 310 (YES in S57), the process ends.

In this way, until it is determined to end the updating of the temperature information 310, the temperature information 310 of the volatile memory is updated whenever the read operation of the nonvolatile memory 100 is executed by the number of times Tnr.

With the above configuration, the read voltage based on the latest temperature can be applied when a subsequent read operation is executed.

According to the sixth embodiment, like the memory system according to the first embodiment, by acquiring the latest temperature based on the number of times the operation is executed, it is also possible to acquire information regarding the temperature of the nonvolatile memory 100 at high frequency. Accordingly, it is possible to improve reliability of the memory system 1.

### 7. Seventh Embodiment

In the above-described first to sixth embodiments, as described in the example, during the operation or the process, based on the period and the number of times the operation or the process is executed (e.g., execution count), the memory controller acquires the temperature of the nonvolatile memory, but an embodiment is not limited thereto. The memory controller 200 may be configured to acquire the temperature of the nonvolatile memory based on a variation in a temperature of the own memory controller 200.

Hereinafter, a configuration and an operation of the memory system 1 according to the seventh embodiment will be described.

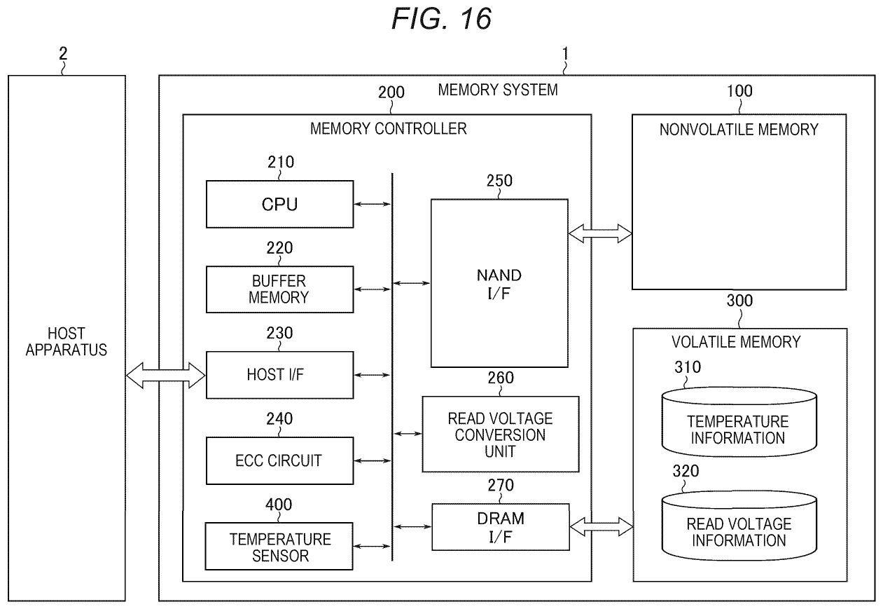

First, a configuration of the memory system 1 according to the seventh embodiment will be described with reference to FIG. 16. FIG. 16 is a block diagram illustrating an example of a configuration including a memory system and a host apparatus according to the seventh embodiment. Hereinafter, differences between a configuration of a memory system according to the seventh embodiment and the configuration of the memory system according to the first embodiment will be described.

In the seventh embodiment, the memory controller 200 further includes a temperature sensor 400. The temperature sensor 400 is configured to be able to measure a temperature in the memory controller 200. The temperature measured by the temperature sensor 400 is temporarily stored in, for example, the buffer memory 220.

For example, the memory controller 200 is configured to transmit the temperature acquisition command to the nonvolatile memory 100 based on the variation in the temperature calculated using a measurement result of the temperature sensor 400 under the control of the processor 210. More specifically, the memory controller 200 is configured to measure a temperature of the memory controller 200 by the temperature sensor 400, for example, whenever a predetermined period passes. For example, when the temperature of the memory controller 200 is measured by the temperature sensor 400, the memory controller 200 calculates a difference (absolute value) between a measured latest temperature and an immediately previous temperature measured by the temperature sensor 400. For example, the memory controller 200 determines whether the difference is greater than a predetermined value (e.g., a condition is satisfied where the temperature variation exceeds a defined threshold). When the difference is greater than the predetermined value, the memory controller 200 determines that the variation in the temperature is detected and transmits the temperature acquisition command to the nonvolatile memory 100. When the difference is equal to or less than the predetermined value, the memory controller 200 determines that the variation in the temperature is not detected and does not transmit the temperature acquisition command.

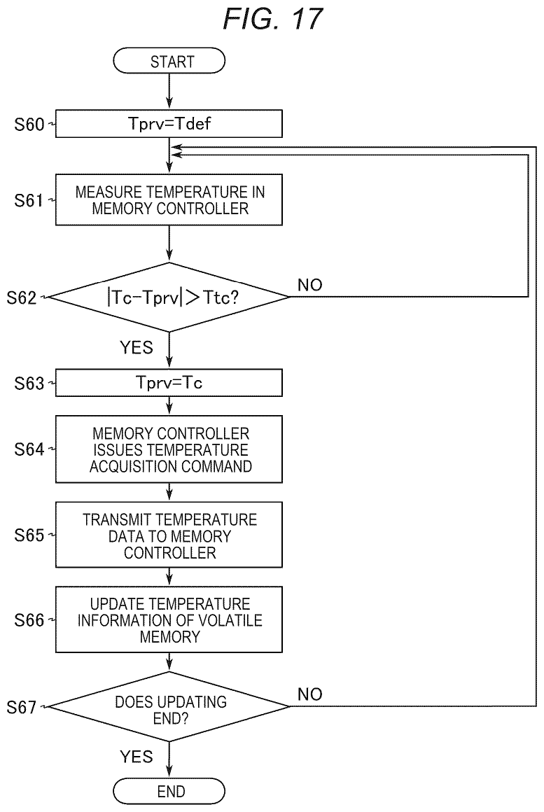

Next, an operation of the memory system 1 according to the seventh embodiment will be described with reference to FIG. 17. FIG. 17 is a flowchart illustrating an operation example in the memory system according to the seventh embodiment.

When the operation of the memory system 1 according to the seventh embodiment starts, the memory controller 200 sets a temperature Tprv to a temperature Tdef (Tprv=Tdef) in S60. Then, the process proceeds to S61. The temperature Tdef is, for example, a regular temperature or a temperature of the memory controller 200 when the operation of the memory system 1 starts.

In S61, the temperature sensor 400 measures a temperature Tc of the memory controller 200. Then, the process proceeds to S62.

In S62, the memory controller 200 determines whether a difference (|Tc−Tprv|) between the temperature Tc and the temperature Tprv is greater than a predetermined value Ttc (a threshold of the difference |Tc−Tprv|). When the difference is greater than the value Ttc (YES in S62), the process proceeds to S63. When the difference is equal to or less than the value Ttc (NO in S62), the process of S61 is executed again.

In S63, the memory controller 200 sets the temperature Tprv to the temperature Tc. Then, the process proceeds to S64.

In S64, the memory controller 200 transmits, for example, the temperature acquisition command to the nonvolatile memory 100. Accordingly, in the nonvolatile memory 100, the temperature sensor 24 starts the temperature measurement.

When the temperature measurement by the temperature sensor 24 ends, the nonvolatile memory 100 transmits the latest temperature as the temperature data Temp_info to the memory controller 200 in S65. Then, the process proceeds to S66.

In S66, based on the temperature data Temp_info, the temperature information 310 of the volatile memory 300 is updated. For example, based on the temperature data Temp_info, the memory controller 200 calculates the read voltage based on the latest temperature and updates the read voltage information 320. Then, the process proceeds to S67.

In S67, the memory controller 200 determines whether to end the updating of the temperature information 310. When the memory controller 200 determines not to end the updating of the temperature information 310 (NO in S67), the process of S61 is executed again. When the memory controller 200 determines to end the updating of the temperature information 310 (YES in S67), the process ends.

In this way, when the difference (|Tc−Tprv|)) between the temperature Tc in the memory controller 200 and the temperature Tprv in the memory controller 200 stored during the updating of the temperature information 310 at the previous time is greater than the value Ttc, the temperature information 310 regarding the nonvolatile memory 100 is updated. That is, when the variation in the temperature in the memory controller 200 is detected, the memory controller 200 estimates that the temperature varies in the nonvolatile memory 100 and updates the temperature information 310.

With the above configuration, when a subsequent read operation is executed, the read voltage based on the latest temperature can be applied.

In the seventh embodiment, by updating the temperature information 310 based on the variation in the temperature of the memory controller 200, like the memory system according to the first embodiment, it is also possible to acquire information regarding the temperature of the nonvolatile memory 100 at high frequency. Accordingly, it is possible to improve reliability of the memory system 1.

### 8. Eighth Embodiment

In an eighth embodiment, an example in which the memory controller acquires a temperature of the nonvolatile memory based on the number of fail bits detected during execution of a read operation will be described.

Hereinafter, a configuration and an operation of the memory system 1 according to the eighth embodiment will be described.

First, differences between a configuration of a memory system 1 according to the eighth embodiment and the configuration of the memory system according to the first embodiment will be described.

In the eighth embodiment, the memory controller 200 is configured to be able to count the number of fail bits fbc during a read operation executed in the nonvolatile memory 100. The memory controller 200 is configured to be able to determine whether the number of fail bits fbc is greater than the predetermined value Tfbc (e.g., a condition is satisfied where the fail-bit count exceeds a threshold Tfbc). The memory controller 200 is configured to transmit the temperature acquisition command to the nonvolatile memory 200 when the number of fail bits fbc in the nonvolatile memory 100 is greater than the predetermined value Tfbc.

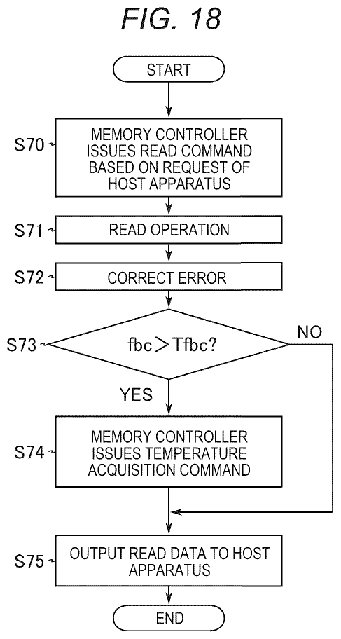

Next, an operation of the memory system 1 according to the eighth embodiment will be described with reference to FIG. 18. FIG. 18 is a flowchart illustrating an operation example in a memory system according to the eighth embodiment.

In S70, the memory controller 200 transmits a read command for requiring the nonvolatile memory 100 to execute a read operation in response to a request of the host apparatus 2. Then, the process proceeds to S71.

In S71, the read operation in the nonvolatile memory 100 is executed. Then, the process proceeds to S72.

In S72, the memory controller 200 determines whether the number of fail bits fbc is greater than the predetermined value Tfbc (fbc>Tfbc?) when the read operation is executed. When the number of fail bits fbc is greater than the predetermined value Tfbc (YES in S73), the process proceeds to S74. When the number of fail bits fbc is equal to or less than the predetermined value Tfbc (NO in S73), the process proceeds to S75.

In S74, for example, the memory controller 200 transmits the temperature acquisition command to the nonvolatile memory 100. Accordingly, in the nonvolatile memory 100, the temperature sensor 24 starts the temperature measurement. Then, the process proceeds to S75. The operation in response to the temperature acquisition command is the same as, for example, the processes of S32 and S33 of the fourth embodiment. These processes can be executed independently from the operation example in the memory system according to the eighth embodiment.

In S75, the memory controller 200 transmits the read data in S71 to the host apparatus 2. Then, the process ends.

In this way, the memory controller 200 updates the temperature information 310 of the nonvolatile memory 100 based on the number of fail bits when there is a read request given from the host apparatus 2.

With the above configuration, the read voltage that is based on the latest temperature can be applied when a subsequent read operation is executed.

According to the eighth embodiment, like the memory system according to the first embodiment, by updating the temperature information 310 based on the number of fail bits fbc in the read operation, it is also possible to acquire information regarding the temperature of the nonvolatile memory 100 at high frequency. Accordingly, it is possible to improve reliability of the memory system 1.

### 9. Others

In the above-described first embodiment, as described in the example, the memory controller 200 transmits the command “ZZh” for giving an instruction to update the temperature information 310 before the commands “A2h”, “00h”, and “30h” and the address ADD transmitted for the nonvolatile memory 100 to execute the read operation, but an embodiment is not limited thereto. For example, the memory controller 200 may be configured to transmit a command for giving an instruction to update the temperature information 310 like the first embodiment immediately before the command transmitted for the nonvolatile memory 100 to execute a write operation or an erase operation. In this case, like the first embodiment, for example, when the various operations end in the nonvolatile memory 100 and the nonvolatile memory 100 enters the ready state from the busy state, the temperature data is transmitted from the nonvolatile memory 100 to the memory controller 200.

In the above-described second and third embodiments, as described in the example, while the read operation is executed in the nonvolatile memory 100 and the nonvolatile memory 100 is in the busy state, the temperature acquisition command “7Ch” is transmitted, but an embodiment is not limited thereto. For example, while the write operation or the erase operation in the nonvolatile memory 100 is executed and the nonvolatile memory 100 is in the busy state, the memory controller 200 may transmit the temperature acquisition command “7Ch”.

In the above-described sixth embodiment, as described in the example, the temperature acquisition command “7Ch” is transmitted based on the number of times the read operation is executed, but an embodiment is not limited thereto. The memory controller 200 may transmit the temperature acquisition command “7Ch” based on the number of times a predetermined operation is executed. The predetermined operation is, for example, a write operation, an erase operation, or a predetermined operation other than the read operation, the write operation, and the erase operation. The number of times the predetermined operation is executed may be the number of times one of the read operation, the write operation, and the erase operation is executed.

Although not illustrated, the nonvolatile memory 100 may include a plurality of chips. In this case, each chip has a configuration substantially the same as the configuration of the nonvolatile memory in the first embodiment. The NAND interface circuit 250 is configured to be able to independently communicate with each chip of the nonvolatile memory 100. Accordingly, when the nonvolatile memory 100 includes the plurality of chips, operations similar to the operations of the nonvolatile memory in the above-described first to eighth embodiments are implemented.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A memory system, comprising:
a nonvolatile memory comprising:
a plurality of memory cells;
a temperature sensor configured to acquire temperature data through temperature measurement; and
and a buffer configured to store the temperature data;
a memory controller; and
wherein when the nonvolatile memory executes a first operation in response to a first instruction transmitted from the memory controller, the temperature sensor acquires the temperature data representing a temperature of the nonvolatile memory in the first operation and the buffer stores the temperature data acquired by the temperature sensor as updated data;
wherein the nonvolatile memory transmits the temperature data stored in the buffer to the memory controller in response to a second instruction transmitted from the memory controller.

2. The memory system of claim 1, wherein the first operation is a read operation, a write operation, or an erase operation in the nonvolatile memory.

3. The memory system of claim 1, wherein the temperature sensor executes temperature measurement on the nonvolatile memory for a first period after the first operation starts.

4. The memory system of claim 3, wherein the memory controller transmits the second instruction to the nonvolatile memory before transmitting the first instruction.

5. The memory system of claim 4, wherein:
the first operation is a read operation; and
the nonvolatile memory transmits the temperature data stored in the buffer to the memory controller continuously with read data from the first operation after the nonvolatile memory executes the first operation in response to the first instruction.

6. The memory system of claim 3, wherein the memory controller transmits the second instruction after the nonvolatile memory starts executing the first operation in response to the first instruction.

7. The memory system of claim 3, wherein:
the memory controller comprises a temperature information determinator; and
when the temperature measurement on the nonvolatile memory is executed for the first period, the temperature sensor causes the buffer to store first data indicating that an accurate temperature is not available for transmission and causes the buffer to store the temperature data after the first period passes.

8. The memory system of claim 7, wherein:
when the second instruction is received from the memory controller within the first period, the nonvolatile memory transmits the first data to the memory controller;
the temperature information determinator determines whether data from the nonvolatile memory with regard to the second instruction is the first data; and
the memory controller transmits the second instruction again to the nonvolatile memory when the temperature information determinator determines that the first data is received from the nonvolatile memory.

9. The memory system of claim 3, wherein:
the memory controller comprises a period determinator that determines whether the first period passes after the first operation starts, and
the memory controller transmits the second instruction to the nonvolatile memory when the period determinator determines that the first period passes.

10. The memory system of claim 1, further comprising:
a volatile memory configured to store temperature information corresponding to the temperature of the nonvolatile memory;
wherein the memory controller updates the temperature information using the temperature data received from the nonvolatile memory and provides an instruction to execute a read operation using a read voltage converted based on the temperature information when an instruction to execute a read operation is provided to the nonvolatile memory.

11. The memory system of claim 1, wherein the nonvolatile memory is configured to transmit read data in the nonvolatile memory to the memory controller via the buffer.

12. A memory system comprising:
a nonvolatile memory comprising a plurality of memory cells and a first temperature sensor configured to acquire temperature data through temperature measurement; and
a memory controller;
wherein when a first condition is satisfied:
the memory controller transmits a first instruction for instructing the nonvolatile memory to acquire the temperature data;
the first temperature sensor acquires the temperature data corresponding to a temperature of the nonvolatile memory in response to the first instruction; and
the nonvolatile memory transmits the acquired temperature data to the memory controller.

13. The memory system of claim 12, wherein the first condition is a condition that a power-off process of the nonvolatile memory, a standby process of the nonvolatile memory, a power-on process of the nonvolatile memory that is powered off, or a recovery process of the nonvolatile memory in a standby state is executed.

14. The memory system of claim 13, wherein:
the memory controller is configured to determine whether a first period that passes from start of counting of a time is less than a second period determined in advance;
the first condition is a condition that the memory controller determines that the first period is equal to or greater than the second period; and
when the memory controller determines that the first period is equal to or greater than the second period, the memory controller resets the first period and resumes the counting of the time.

15. The memory system of claim 12, wherein:
the memory controller is configured to determine whether a first execution count of a first operation is executed is less than a second execution count determined in advance;
wherein the first condition is a condition that the memory controller determines that the first execution count is equal to or greater than the second execution count.

16. The memory system of claim 15, wherein:
when the memory controller determines that the first execution count is equal to or greater than the second execution count, the memory controller resets the first execution count and resumes the counting of the first execution count.

17. The memory system of claim 15, wherein the first operation is a read operation, a write operation, or an erase operation on the nonvolatile memory or one of the read operation, the write operation, and the erase operation.

18. The memory system of claim 12, wherein:
the memory controller comprises a second temperature sensor configured to acquire temperature data through temperature measurement and is configured to detect a variation in temperature based on temperature measurement of the second temperature sensor; and
the first condition is a condition that the memory controller detects the variation in temperature.

19. The memory system of claim 12, wherein:
the memory controller is configured to count a number of fail bits in a read operation for data stored in the nonvolatile memory; and
the first condition is a condition that the counted number of fail bits is greater than a predetermined value.
